(19) United States
(12) Patent Application Publication
(10) Pub. No.: US 2017/0166055 A1
(43) Pub. Date: Jun. 15, 2017

(54) Methods and Systems for Interactive Passenger Notification

(71) Applicant: Myine Electronics, Inc., Ferndale, MI (US)

(72) Inventors: Corey MAYLONE, Berkley, MI (US); John BYRNE, Detroit, MI (US); Scott SMEREKA, Warren, MI (US); Joey Ray GROVER, Madison Heights, MI (US); Justin DICKOW, Royal Oak, MI (US); Joel J. FISCHER, Royal Oak, MI (US)

(21) Appl. No.: 14/965,181

(22) Filed: Dec. 10, 2015

(51) Int. Cl. B60K 35/00; B60H 1/00; B60R 16/037; G01C 21/36

(52) U.S. Cl. CPC B60K 35/00; G01C 21/3664; B60H 1/00985; B60R 16/037; B60K 2350/1004; B60K 2350/1028; B60K 2350/106

(57) ABSTRACT

A vehicle system includes a processor programmed to receive a suggested infotainment setting via occupant input. The processor is further programmed to transmit the suggested infotainment setting to one or more devices for occupant feedback and control an infotainment feature in response to the received occupant feedback to accept, reject, or modify the suggested infotainment setting.

### TECHNICAL FIELD

The present disclosure generally relates to an infotainment system that may receive user feedback from a mobile device to influence the content and the manner in which the infotainment system operates.

### BACKGROUND

A vehicle computing system is used to provide several features and functions including hands-free calling, navigation information and music to vehicle occupants while traveling to a destination. The vehicle computing system may provide settings to allow configuration of certain vehicle features and functions based on an occupant's preference. The settings may be manually configured once the occupant enters the vehicle. For example, the vehicle computing system may be configured to adjust climate control settings at the vehicle via a knob or button associated with the climate control settings. The climate control settings may be initiated using physically-actuated vehicle inputs manipulated by the vehicle occupant.

In some cases, the vehicle occupant may wish to perform a number of functions, however, may not have access to the settings based on seating position within a vehicle cabin, or different occupants may want to control the same feature or function. For example, a vehicle occupant sitting in a backseat of the vehicle cabin may not like a suggested music selection made by a frontseat passenger. The backseat passenger may want to provide input for the music selection, however, may not have access to the settings interface. In addition, the backseat passenger may not provide input to settings for other vehicle features and functions since they do not have access to the physically-actuated inputs such as the knob or button associated with a navigation destination, a climate control setting, or controls associated with music playing in the vehicle.

### SUMMARY

In at least one embodiment, a vehicle system includes a processor programmed to receive a suggested infotainment setting via occupant input. The processor is further programmed to transmit the suggested infotainment setting to one or more devices for occupant feedback and control an infotainment feature in response to the received occupant feedback to accept, reject, or modify the suggested infotainment setting.

In at least one embodiment, a method uses a processor to transmit a setting suggestion request to control an infotainment feature to one or more devices. The method includes receiving a suggested answer associated with the setting suggestion request from the one or more devices. The method further includes outputting an option list having the suggested answer to a designated device such that the option list provides some or all of the suggested answers received from each device. The option list allows an occupant associated with the designated device to control an infotainment feature based on a selected answer via the option list.

In at least one embodiment, a computer-program product embodied in a non-transitory computer readable medium having stored instructions for programming a processor comprises instructions for transmitting an infotainment feature setting adjustment option to one or more devices via a transceiver for occupant feedback to accept, reject, or modify the setting adjustment option. The computer-program product includes further instructions for controlling the infotainment feature in response to arbitration of received occupant feedback if more than one of an accept, deny, or modify the setting adjustment option is received. In one embodiment, the arbitration may select the setting adjustment option having feedback that exceeds a predefined majority threshold value.

### BRIEF DESCRIPTION OF THE DRAWINGS

FIG. 1 is a representative topology of a vehicle computing system implementing a user-interactive vehicle information display system according to an embodiment;

FIG. 2 shows an illustrative example of one or more remote devices running one or more applications in communication with the vehicle computing system according to an embodiment;

FIG. 3 shows an illustrative example of the one or more remote devices providing a destination suggestion for the vehicle computing system according to an embodiment;

FIG. 4 shows a block diagram illustrating the vehicle computing system in communication with one or more remote devices according to an embodiment;

FIG. 5 is a flow chart illustrating an example method of the vehicle computing system communicating with the one or more remote devices; and

FIG. 6 is a flow chart illustrating an example method to adjust a music selection at the vehicle computing system via the one or more remote devices.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

The embodiments of the present disclosure generally provide for a plurality of circuits or other electrical devices. All references to the circuits and other electrical devices and the functionality provided by each, are not intended to be limited to encompassing only what is illustrated and described herein. While particular labels may be assigned to the various circuits or other electrical devices disclosed, such labels are not intended to limit the scope of operation for the circuits and the other electrical devices. Such circuits and other electrical devices may be combined with each other and/or separated in any manner based on the particular type of electrical implementation that is desired. It is recognized that any circuit or other electrical device disclosed herein may include any number of microprocessors, integrated circuits, memory devices (FLASH, random access memory (RAM), read only memory (ROM), electrically programmable read only memory (EPROM), electrically erasable programmable read only memory (EEPROM), or other suitable variants thereof, for example) and software which co-act with one another to perform operation(s) disclosed herein. In addition, any one or more of the electric devices may be configured to execute a computer-program that is embodied in a non-transitory computer readable medium that is programmed to perform any number of the functions as disclosed.

The disclosure relates to a vehicle computing system configured to improve the driving experience by controlling one or more infotainment feature settings based on passenger feedback. The vehicle computing system may communicate a request notification to one or more remote devices associated with a passenger to manage an infotainment action for infotainment features. Based on received feedback associated with the request notification via the one or more remote devices, the vehicle computing system may adjust an infotainment setting.

The vehicle computing system is configured to connect with the one or more remote devices via an application. The application manages the request notification for the infotainment features communicated to the devices including media information, travel time, or other infotainment feature information. The one or more remote devices associated with a passenger may enable the passenger to communicate infotainment setting options and preferences with other vehicle occupants via the vehicle computing system.

For example, the vehicle computing system may present a question selected by a driver to the one or more devices associated with one or more passengers. The vehicle computing system may determine a quorum answer based on responses from the one or more passengers via their respective device. The quorum includes a statistical analysis of the feedback responses received from the one or more remote devices in communication with the vehicle computing system. In response to the passenger feedback, the vehicle computing system may perform the infotainment action of adjusting an infotainment setting. The infotainment action may include, but is not limited to, skipping a song being played, updating the navigation system to a new destination, and determining whether or not the driver should stop for food using the statistical analysis approach based on the passenger feedback responses.

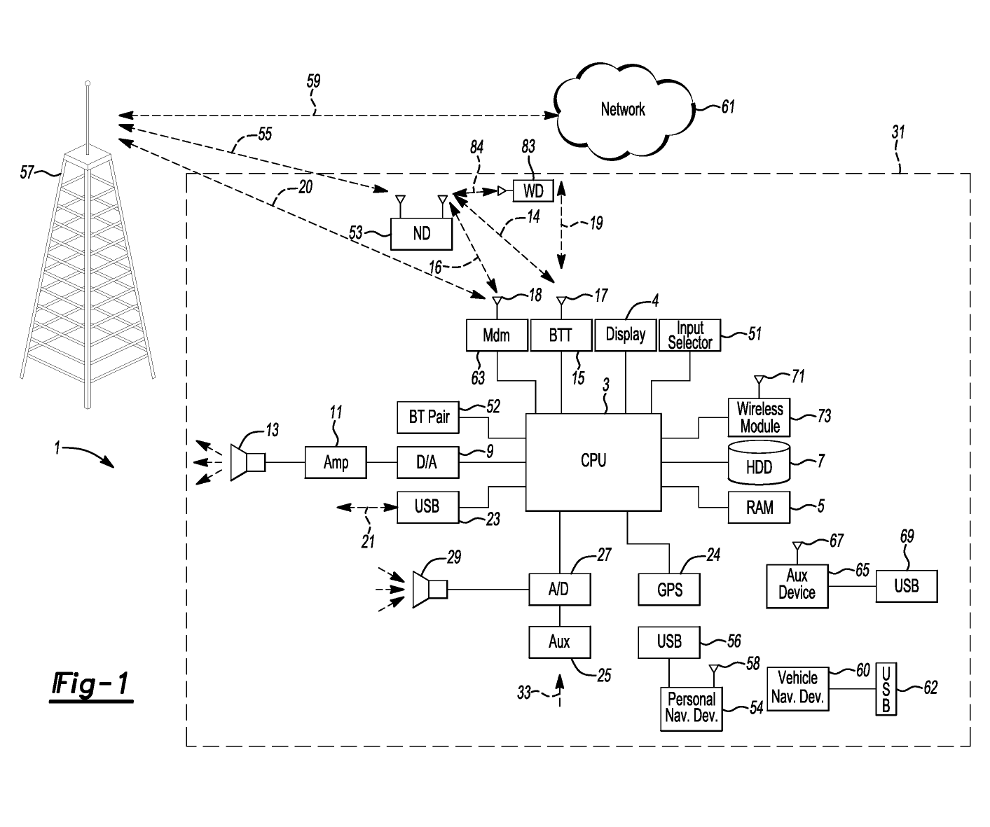

FIG. 1 illustrates an example block topology for the VCS 1 for a vehicle 31. An example of such a VCS 1 is the SYNC system manufactured by THE FORD MOTOR COMPANY. A vehicle enabled with a vehicle-based computing system may contain a visual front end interface 4 located in the vehicle. The user may also be able to interact with the interface if it is provided, for example, with a touch sensitive screen. In another illustrative embodiment, the interaction occurs through, button presses, or a spoken dialog system with automatic speech recognition and speech synthesis.

In the illustrative embodiment 1 shown in FIG. 1, a processor 3 controls at least some portion of the operation of the vehicle-based computing system. Provided within the vehicle, the processor allows onboard processing of commands and routines. Further, the processor 3 is connected to both non-persistent 5 and persistent storage 7. In this illustrative embodiment, the non-persistent storage is random access memory (RAM) and the persistent storage is a hard disk drive (HDD) or flash memory. In general, persistent (non-transitory) memory can include all forms of memory that maintain data when a computer or other device is powered down. These include, but are not limited to, HDDs, CDs, DVDs, magnetic tapes, solid state drives, portable USB drives and any other suitable form of persistent memory.

The processor 3 is also provided with a number of different inputs allowing the user to interface with the processor. In this illustrative embodiment, a microphone 29, an auxiliary input 25 (for input 33), a USB input 23, a GPS input 24, screen 4, which may be a touchscreen display, and a BLUETOOTH input 15 are all provided. An input selector 51 is also provided, to allow a user to swap between various inputs. Input to both the microphone and the auxiliary connector is converted from analog to digital by a converter 27 before being passed to the processor. Although not shown, numerous vehicle components and auxiliary components in communication with the VCS 1 may use a vehicle network (such as, but not limited to, a CAN bus) to pass data to and from the VCS 1 (or components thereof).

In one example, the number of different inputs may be associated with a setting for one or more vehicle features. In response to received input to adjust the setting associated with a vehicle feature, the processor 3 may communicate the adjusted setting to the vehicle feature via the vehicle network.

Outputs to the system may include, but are not limited to, a visual display 4 and a speaker 13 or stereo system output. The speaker 13 is connected to an amplifier 11 and receives its signal from the processor 3 through a digital-to-analog converter 9. Output can also be made to a remote BLUETOOTH device such as PND 54 or a USB device such as vehicle navigation device 60 along the bi-directional data streams shown at 19 and 21 respectively.

In one illustrative embodiment, the system 1 uses the BLUETOOTH transceiver 15 to communicate 17 with a user's nomadic device 53 (cell phone, smartphone, tablet, PDA, or any other remote device having wireless remote network connectivity, for example). The nomadic device 53 may then be used to communicate 59 with a network 61 outside the vehicle 31 through, for example, communication 55 with a cellular tower 57. In some embodiments, tower 57 may be a WiFi access point. The nomadic device 53 may also be used to communicate 84 with an accessory device such as a wearable device 83 (smartwatch, smart glasses, etc., for example). The nomadic device 53 may communicate one or more control functions to the wearable device 83. For example, the nomadic device 53 may enable the wearable device 83 to accept a phone call, enable a mobile application, receive notifications, and/or a combination thereof. In another example, the wearable device 83 may transmit vehicle control features/functions to the VCS 1 based on one or more mobile applications executed at the nomadic device 53.

Communication between the nomadic device 53 and the BLUETOOTH transceiver 15 is represented by signal 14. Pairing a nomadic device 53 and the BLUETOOTH transceiver 15 can be instructed through a button 52 or similar input. Accordingly, the CPU 3 is instructed so that the onboard BLUETOOTH transceiver 15 may be paired with a BLUETOOTH transceiver in a nomadic device 53. In another example, the wearable device 83 and the BLUETOOTH transceiver 15 is represented by signal 14. Comparable to the nomadic device BLUETOOTH pairing process, pairing a wearable device 83 and the BLUTOOTH transceiver 15 can be instructed through a button 52 or similar input. The onboard BLUETOOTH transceiver 15 may be paired with a BLUETOOTH transceiver in a wearable device 83.

The processor 3 may be configured to transmit information to a previously paired nomadic and/or wearable device 53, 83 (a remote device, for example). The processor 3 may be configured to request communication with a previously paired remote device. For example, in response to the requested communication from the processor 3, the previously paired remote device 53 may transmit an established communication message to the processor 3.

Data may be communicated between CPU 3 and network 61 utilizing, for example, a data-plan, data over voice, or DTMF tones associated with remote device 53. Alternatively, it may be desirable to include an onboard modem 63 having an antenna 18 in order to communicate 16 data between CPU 3 and network 61 over the voice band. The remote device 53 may then be used to communicate 59 with a network 61 outside the vehicle 31 through, for example, communication 55 with a cellular tower 57. In some embodiments, the modem 63 may establish communication 20 with the tower 57 for communicating with network 61. As a non-limiting example, modem 63 may be a USB cellular modem and communication 20 may be cellular communication.

In one illustrative embodiment, the processor 3 is provided with an operating system including an application program interface (API) to communicate with modem application software. The modem application software may access an embedded module or firmware on the BLUETOOTH transceiver to complete wireless communication with a remote BLUETOOTH transceiver (such as that found in a remote device 53). Bluetooth is a subset of the IEEE 802 PAN (personal area network) protocols. IEEE 802 LAN (local area network) protocols include Wi-Fi and have considerable cross-functionality with IEEE 802 PAN. Both are suitable for wireless communication within a vehicle. Another communication means that can be used in this realm is free-space optical communication (such as IrDA) and non-standardized consumer IR protocols.

In another embodiment, the remote device 53 includes a modem for voice band or broadband data communication. In the data-over-voice embodiment, a technique known as frequency division multiplexing may be implemented when the owner of the remote device 53 can talk over the device while data is being transferred. At other times, when the owner is not using the device, the data transfer can use the whole bandwidth (300 Hz to 3.4kHz in one example). While frequency division multiplexing may be common for analog cellular communication between the vehicle and the internet, and is still used, it has been largely replaced by hybrids of Code Domain Multiple Access (CDMA), Time Domain Multiple Access (TDMA), Space-Domain Multiple Access (SDMA) for digital cellular communication. These are all ITU IMT-2000 (3G) compliant standards and offer data rates up to 2 mbs for stationary or walking users and 385 kbs for users in a moving vehicle. 3G standards are now being replaced by IMT-Advanced (4G) which offers 100 mbs for users in a vehicle and 1 gbs for stationary users. If the user has a data-plan associated with the remote device 53, it is possible that the data- plan allows for broad-band transmission and the system could use a much wider bandwidth (speeding up data transfer). In still another embodiment, remote device 53 is replaced with a cellular communication device (not shown) that is installed to vehicle 31. In yet another embodiment, the remote device 53 may be a wireless local area network (LAN) device capable of communication over, for example (and without limitation), an 802.11g network (i.e., WiFi) or a WiMax network.

In one embodiment, incoming data can be passed through the remote device 53 via a data-over-voice or data-plan, through the onboard BLUETOOTH transceiver and into the vehicle's internal processor 3. In the case of certain temporary data, for example, the data can be stored on the HDD or other storage media 7 until such time as the data is no longer needed.

Additional sources that may interface with the vehicle include a personal navigation device 54, having, for example, a USB connection 56 and/or an antenna 58, a vehicle navigation device 60 having a USB 62 or other connection, an onboard GPS device 24, or remote navigation system (not shown) having connectivity to network 61. In another example, the wireless device (nomadic device 53, wearable device 83, etc., for example) may communicate with the processor via USB connection. USB is one of a class of serial networking protocols. IEEE 1394 (FireWire™ (Apple), i.LINK™ (Sony), and Lynx™ (Texas Instruments)), EIA (Electronics Industry Association) serial protocols, IEEE 1284 (Centronics Port), S/PDIF (Sony/Philips Digital Interconnect Format) and USB-IF (USB Implementers Forum) form the backbone of the device-device serial standards. Most of the protocols can be implemented for either electrical or optical communication.

Further, the CPU 3 could be in communication with a variety of other auxiliary devices 65. These devices can be connected through a wireless 67 or wired 69 connections. Auxiliary device 65 may include, but are not limited to, personal media players, wireless health devices, portable computers, and the like.

Also, or alternatively, the CPU 3 could be connected to a vehicle based wireless router 73, using for example a WiFi (IEEE 803.11) 71 transceiver. This could allow the CPU 3 to connect to remote networks in range of the local router 73.

In addition to having representative processes executed by a VCS 1 located in a vehicle, in certain embodiments, the processes may be executed by a computing system in communication with a vehicle computing system. Such a system may include, but is not limited to, a wireless device (a mobile phone, a smartphone, the remote device 53, wearable device 83 etc., for example) or a remote computing system (a server 61, for example) connected through the wireless device. Collectively, such systems may be referred to as vehicle associated computing systems (VACS). In certain embodiments particular components of the VACS may perform particular portions of a process depending on the particular implementation of the system. By way of example and not limitation, if a process includes sending or receiving information with a paired wireless device, then it is likely that the wireless device is not performing the process, since the wireless device would not “send and receive” information with itself. One of ordinary skill in the art will understand when it is inappropriate to apply a particular VACS to a given solution. In all solutions, it is contemplated that at least the vehicle computing system (VCS) 1 located within the vehicle itself is capable of performing the processes.

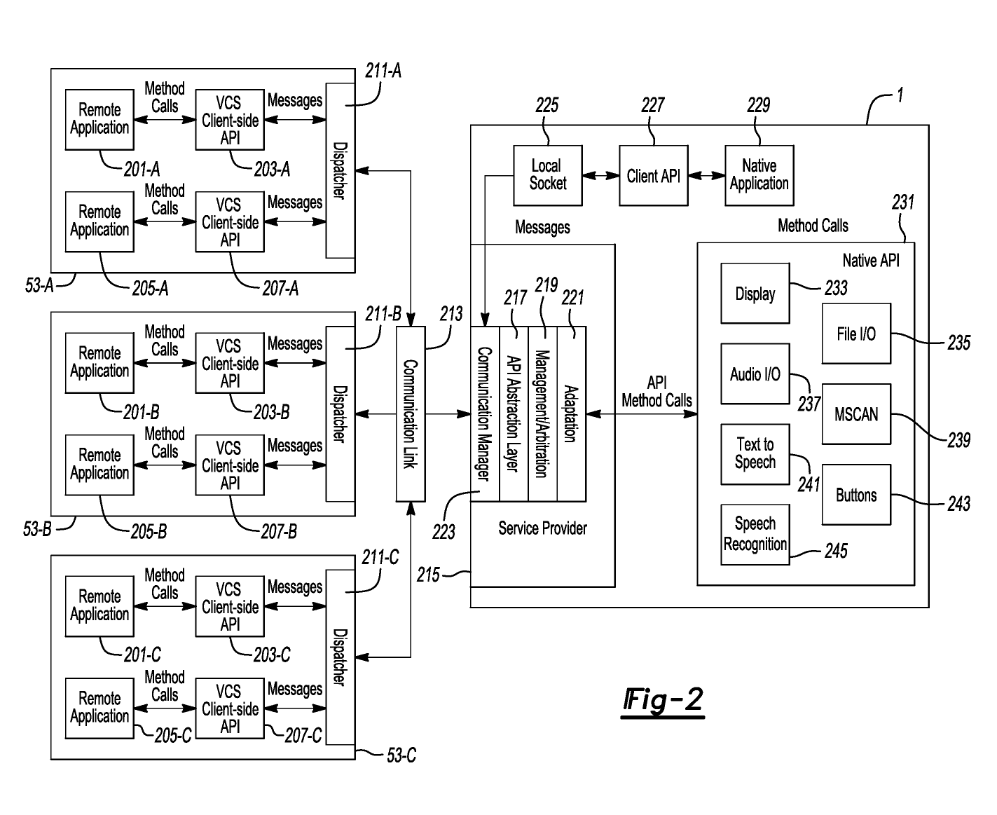

FIG. 2 shows an illustrative example of one or more remote devices 53 running one or more applications in communication with the VCS 1. The remote devices 53-A through 53-C (collectively 53) may be operated by occupants throughout the passenger compartment, including passengers in the rear seats. The illustrative example of one or more remote devices 53 is represented in the figure as an example of multiple devices 53 communicating with the VCS 1.

In this illustrative embodiment, a remote device 53-A (without limitation, a cell phone, PDA, GPS device, etc., for example) has one or more remote applications 201-A though 201-C (collectively 201), and 205-A through 205-C (collectively 205) stored thereon. The remote applications 201, 205 communicate with the VCS 1, using a client side API 203-A through 203-C (collectively 203), and 207-A through 207-C (collectively 207). This API could, for example, be provided to developers in advance, and define the format of outgoing and incoming packets so that communication between the remote device 53 and the VCS 1 is possible. A dispatcher 211-A though 211-C (collectively 211) may be provided to the remote devices 53 if more than one application is communicating at the same time.

Data is passed from the remote device 53 to the VCS 1 through a communication link 213. This communication link maybe a wired or wireless link, and can be half or full duplex. In one non-limiting example, the link is a BLUETOOTH link.

The VCS 1 has various applications stored thereon, including, but not limited to: a communications manager 223, an API abstraction application (or layer) 217, a management and arbitration application 219, and an adaptation application 221 (these applications can also be layers of a single or plurality of applications, such as a service provider application 215).

In this representative implementation, the communication manager 223 handles all transports, forwarding incoming messages to the API abstraction application (or layer) 217, and ensuring that outgoing messages are sent via the proper transport channel. The communication manager 223 may also communicate messages with one or more remote devices 53 connected simultaneously to the VCS 1. The vehicle owner or driver may configure certain communication and priority settings allowing certain devices, or passengers to communicate to the VCS 1.

The abstraction application 217 may transform incoming messages into action to be performed by a service and create outgoing messages out of information and events from local modules. The management and arbitration application 219 virtualizes the VCS 1 for each application by managing use of HMI elements and governing resource consumption. The adaptation application 221 may encapsulate the local API and coexist with core local applications. This application may be modified or replaced to allow a communication connection to be compatible with different versions of the VCS 1 system software.

In at least one implementation, a message protocol may be used to encode messages exchanged between a mobile client (the remote device 53, for example) and the VCS 1 to command and control a Human Machine Interface (HMI) for purposes such as displaying and speaking text, listening, propagating button-pushes, etc. These messages may contain small amounts of data (text phrases, button identifiers, status, thumb-drive file data, configuration data, etc., for example). This protocol, using complementary support provided by the message specification, may permit multiple passenger application sessions to concurrently use a single transport channel.

Other open standard protocols may be used where appropriate and available, such as the A2DP BLUETOOTH profile for streaming audio from the remote device 53 to the vehicle audio system (not all mobile devices support A2DP). However, some open standard protocols are not always available on every remote device, or are not always implemented uniformly. In addition, API support for use of these protocols may not be uniformly implemented on all remote device platforms. Therefore, the function of some open standard protocols (OBEX, for example) may be provided as part of the message protocol, when it is technically simple enough to do and a significant increase in uniformity can be achieved across platforms.

Transports may be configured to support full-duplex communication in order to provide prompt event propagation between passenger applications and the VCS 1. A transport may also support multiple concurrent channels in order to permit concurrent connections from one or more devices.

One or more representative transports are Serial (RS232) and TCP/IP. Serial transport communication with remote devices may be provided, for example, through a BLUETOOTH Serial Profile. Most remote devices 53 support this profile, and most provide a common programming model for its use. The serial programming model is widely used and highly uniform. If the VCS 1 provides Serial-over-USB support, then the Serial transport could be used with any remote device 53 that is USB-connected to the VCS 1 (if that remote device provides support for Serial over its USB connection).

In addition, a TCP/IP transport provides the ability for applications running on the VCS 1 to use the local HMI 4. If the module provides external TCP/IP connectivity in the future, this transport may allow external clients to connect over that TCP/IP connectivity. The socket programming model (including the API, for example) for TCP/IP is typically highly portable. Such an example would be a locally loaded application 229, using a client-side API 227 to communicate through a local socket 225.

In at least one exemplary embodiment, the decoupled nature of the system, where the VCS 1 is unaware of one or more occupant applications until they connect, demands a discovery mechanism where the system and the remote device 53 can discover each other's existence and capabilities.

Multiple discovery is possible, where the remote device 53 passenger may be able to discover the environment, locale and HMI capabilities of the local platform and the system may be able to discover the applications available on the one or more remote devices 53 while having the ability to launch those applications.

In this illustrative embodiment, the native API 231 has various services associated therewith, that may be accessed by remote devices 53 through function calls. For example, a display function 233 may be provided.

The system may provide an API allowing an occupant's applications to write to vehicle displays and query their characteristics. The characteristics of each display may be described generically such that occupant's applications may not require hard coding for individual display types (Type 1 FDM, Type 3 GAP, Type 6 Navigation, etc., for example). Specifically, the system may enumerate each display and indicate each display's intended usage (primary or secondary display). Furthermore, the VCS 1 may enumerate the writable text fields of each display, provide each writable text field's dimensions, and indicate each field's intended general usage. To promote consistency with the current user interface, support for the scrolling of long text may also be included, where permitted by driver distraction rules.

The system may also include text to speech capability 241. The system may provide an API allowing occupant's applications to leverage the VCS 1 text-to-speech functionality. Client applications may also be able to interleave the play of audio icons with spoken text. They may be able to utilize preexisting audio icons or provide short audio files of their own. The format of application provided audio files may be limited to those natively supported.

Further functionality of the illustrative embodiments may include one or more button inputs 243. One example of this would be controlling an application on the one or more remote devices 53 through use of buttons installed in a vehicle (such as steering wheel buttons, for example).

Another representative function could be a speech recognition function 245. The system may provide an API allowing client applications to leverage the VCS 1 speech recognition capabilities. The VCS 1 may provide native speech recognition APIs to provide a simpler development model for client application developers. The speech grammar APIs may also be simplified while retaining most of the native API's flexibility. For example, the VCS 1 (on behalf of client applications, for example) may recognize global voice commands such as “Front Seat Occupant”, “BLUETOOTH Audio” or “USB” and pass control to the appropriate remote device 53 and/or application.

Audio I/O 237 may also be provided. The VCS 1 may provide regulated access to the HMI 4 while enforcing the interface conventions that are coded into core applications. A single “in focus” occupant application executed at the remote device 53 may be allowed primary access to the display, buttons, audio capture or speech engine. Occupants' applications without focus (Text Messaging, Turn By Turn Navigation, etc., for example) may be allowed to make short announcements (“New Message Arrived” or “Turn Left”, for example) via the VCS 1. Stereo audio may continue to play after a remote device 53 audio application.

The VCS 1 may provide an API allowing client applications to capture audio recorded using a microphone. The client application may specify duration of the capture, though capture may be interrupted at any time. Captured audio may be returned to the occupant's application or stored on a local or portable drive. The one or more remote devices 53 may have access to the captured audio and may download the audio to the one or more passenger remote devices 53.

Additionally, file I/O 235 may also be provided with the VCS 1. For example, the VCS 1 may provide an API allowing occupant's applications executed at the remote device 53 to read from, write to, create and/or delete files on a remote drive. Access to the remote drive file system may be restricted in that a client application may only read/edit data in a directory specific to that occupant's application.

Finally, the system can provide various forms of security, to ensure system integrity. The system APIs may be limited to prevent inadvertent or malicious damage to the VCS 1 and vehicle by a passenger application, including (but not limited to): Limited access to the vehicle CAN bus; limited access to a local file system; no or limited access to audio output volume; no access to disable PTT (push-to-talk), menu, or other buttons that a developer may deem essential; and no access to disable system voice commands or media player source commands.

Additionally, passenger applications connecting to the VCS 1 may be approved by the driver or vehicle owner. For example, the following criteria may be used: the driver or vehicle owner may install the passenger application on a remote device 53; passenger applications connecting via BLUETOOTH must be running on a remote device 53 paired by the driver or vehicle owner to the VCS 1; and applications running locally on the VCS 1 must be installed onto the system by the vehicle owner.

Another example of remote devices 53 connecting to the VCS 1 is via a USB port. The passenger's remote device 53 may be connected using a USB port connected to the VCS 1. The driver and/or vehicle owner may approve the connection between the passengers remote device 53 with the VCS 1. The driver and/or vehicle owner may select certain restrictions and priority levels associated with the occupant's remote device 53.

The VCS 1 may also use signed and privileged applications. For example, general applications may be signed with a VIN-specific certificate that allows them to interact only with specific vehicle(s). Certificates may be attached to the application installed when the vehicle owner, driver, or passenger obtains the application from a distribution model. Each certificate may contain an encrypted copy of a VIN-specific key and the application's identity. Upon connecting to the service, the application identity string and certificate are sent to the VCS 1. The VCS 1 decrypts the certificates, and verifies that the VIN key matches the system, and that the application identity matches that which is sent from the application via the remote device 53. If both strings do not match, further messages from the application may not be honored. Multiple keys may be included with an application install to allow the application to be used with multiple vehicles.

In addition to acting as a through-way for published data, the VCS 1 itself may publish data for subscription. For example, GPS data linked to the VCS 1 may be published by the system and subscribed to by applications desiring to use the data. These are just a few non-limiting examples of how publication/subscription may be used in conjunction with the illustrative embodiments.

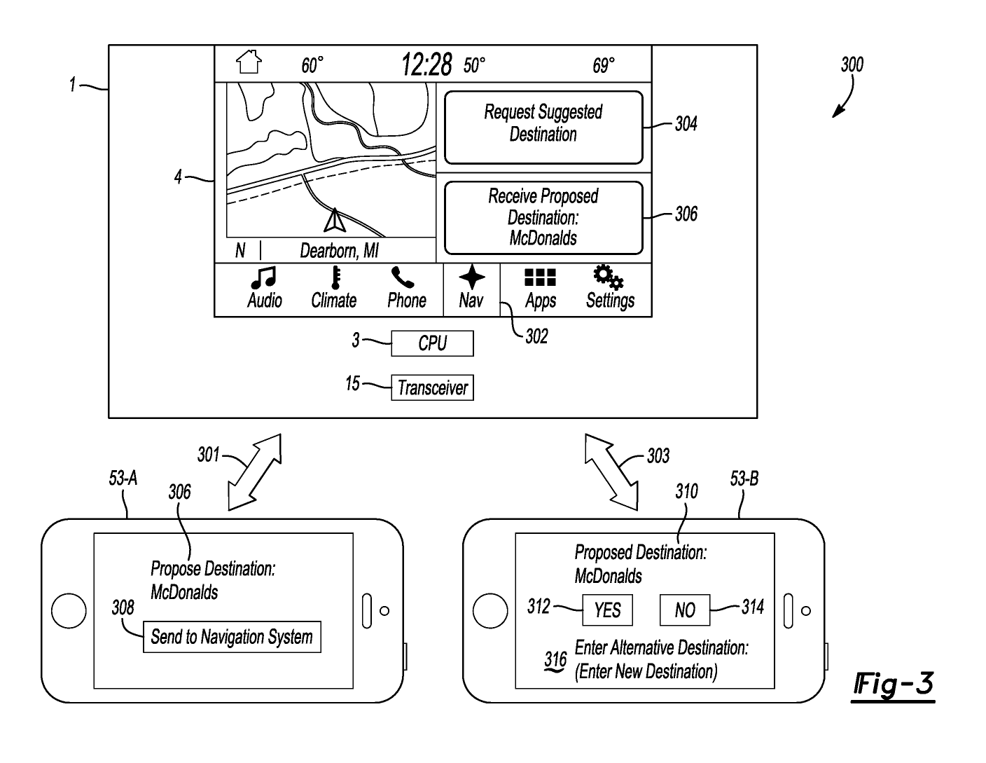

FIG. 3 shows an illustrative example of vehicle components using one or more linked or coupled remote devices 53 to provide a destination suggestion for the VCS 1 according to an embodiment. The VCS 1 may have one or more applications executed on hardware of the system to provide a navigation application 302 at the vehicle user interface display 4. The navigation application 302 may provide an interface to request a suggested destination or to poll connected devices for a suggested destination 304 via the one or more remote devices communicating with the VCS 1. The suggested destination or suggested destination request 304 entered through a vehicle user interface may be used to transmit the request to the one or more remote devices 53 for input relative to the suggested destination or request for a suggested destination as generally indicated by connected devices 53-A and 53-B. As previously described, remote devices 53-A and 53-B may be wirelessly connected through transceiver 15, or linked by a connection through a USB port, for example.

In a representative embodiment, in response to received input at the user interface screen 4 to request a suggested destination 304 from one or more vehicle occupants, the VCS 1 may transmit 301, 303 a request for input related to the suggested destination request to the one or more remote devices 53. A first remote device 53-A may transmit a proposed destination 306 such as going to a McDonalds® restaurant 306. The first remote device 53-A may transmit 301 the proposed destination 306 to the VCS 1 based on user input 308 at the remote device 53 user interface screen. The VCS 1 may receive 301 the proposed destination 306 via the transceiver 15 based on the suggested destination request 304. The VCS 1 may process the proposed destination 306 via the CPU 3. In response to the received proposed destination 306 at the VCS 1, the system may transmit 303 a request to the other remote devices 53 to accept or deny the proposed destination 306. For example, the VCS 1 may transmit 303 to a second remote device 53-B the received proposed destination 306 from the first remote device 53-A.

In response to the proposed destination message from the VCS 1, the second remote device 53-B may output the proposed destination 310, an option whether to accept (“YES” 312) or deny (“NO” 314) the proposed destination, an option to enter an alternative destination 316, and/or a combination thereof. For example, in response to receiving a Yes 312 input via a second mobile device 53-B interface screen, the second remote device 53-B may transmit the accept response to the VCS 1. The VCS 1 may receive the accept response and determine whether or not to generate a route to the proposed destination.

In one example, the VCS 1 may abitrate received occupant feedback by calculating a total number of accept responses compared to a total number of deny responses for determining whether or not to generate a route to the suggested destination. If the VCS 1 calculates a majority vote by having the total number of accept responses received from a majority of vehicle occupants, the system may generate the route from a current vehicle location to the proposed destination. In another example, the VCS 1 may compare the number of accept responses to a predefined threshold value. The predefined threshold value may be a calculated majority ratio based on a number of connected remote devices communicating with the VCS 1. For example, if the accept response exceeds the predefined threshold value, the VCS 1 may accept the proposed destination and generate a route to the destination.

In another example, the VCS 1 may determine whether to adjust a setting of the navigation application based on the predefined threshold taking into consideration a majority factor. The predefined threshold may include the majority factor multiplied by a total amount of occupant responses received from each device. The predefined majority factor may be set to approximately fifty one percent so that the predefined threshold may be equal to a value that is correlated with the number of devices providing occupant feedback. Of course, various other arbitration strategies are possible depending on the particular application and implementation.

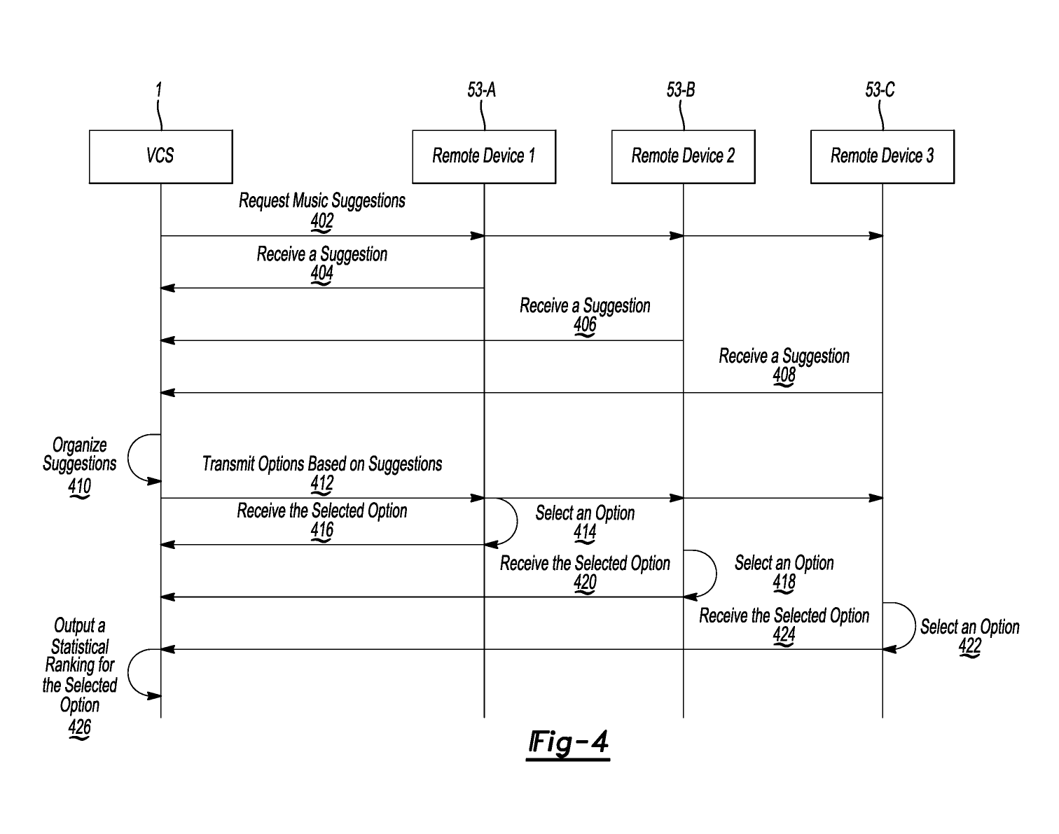

FIG. 4 shows a block diagram illustrating the VCS 1 in communication with one or more remote devices 53 according to an embodiment. The VCS 1 may include one or more processors (CPU 3, for example), at least one wireless transceiver 15, and an in-vehicle display 4. The VCS 1 may communicate with the one or more remote device 53 via the at least one transceiver. The one or more remote devices 53 may include one or more processors, a wireless transceiver, and a remote device user interface display.

The VCS 1 may establish communication with the one or more remote devices 53 via a handshake process. The handshake process may include a series of communications back and forth between the VCS 1 and the one or more remote devices 53 for system access authentication purposes. If the handshake is complete, the VCS 1 may receive data from an application executed at the remote device 53. For example, the handshake process may include the exchange of information to detect whether or not the remote device 53 has been paired with the VCS 1. In another example, the VCS 1 may be executing an application associated with the remote device 53. The application may have a key configured to verify that the VCS 1 is authorized to communicate with the remote device 53.

The VCS 1 may request a music suggestion 402 from the one or more remote devices 53 based on user input received at a vehicle user interface. In response to receiving the requested music suggestion 402, the first remote device 53-A may output a message to the device user interface screen requesting a suggestion for music from the vehicle occupant associated with the device. The VCS 1 may receive a suggestion from the first remote device 53-A based on feedback from the vehicle occupant entering the suggestion via the device user interface screen. The VCS 1 may also receive additional suggestions 406, 408 from the second 53-B and/or third 53-C remote devices.

In response to the received suggestions, the VCS 1 may organize the suggested music 410 into an options list based on the feedback from the vehicle occupants via their remote devices 53. The VCS 1 may transmit the options list 412 to the one or more remote devices 53. For example, the second remote device 53-B may output the options list to the device user interface screen. The second remote device 53-B may receive user input based on the presented options list via the device user interface screen. In response to a received selection 414, 418, 422 from the options list at the device user interface screen, the VCS 1 may receive the selected option 416, 420, 424 from the first 53-A, second 53-B, and/or third 53-C remote device, respectively.

The VCS 1 may generate a statistical ranking for the received selected options so that the system may output a music suggestion 426 corresponding to a majority or plurality of selections. For example, the statistical ranking may calculate a total number of responses received from the option list. In response to the total number of responses received from the option list, the VCS 1 may compare each selection from the option list to the total number of responses. The VCS 1 may determine the option that received the majority of the selections based on the comparison. In another example, the VCS 1 may compare each received selection from the option list to a predefined threshold value. The predefined threshold value is a majority calculation ratio for the number of remote devices 53 communicating with the VCS 1. If the VCS 1 determines that there is no majority vote based on the received selection from the option list, the system may have default rules that implement the selection from a device that may have priority.

For example, the VCS 1 may assign a remote device 53 belonging to a front seat passenger as a default selection for the option list if no majority vote selection is determined based on the statistical ranking calculation for the received selections. In another example, the VCS 1 may implement all the selected options in a predefined order if no majority vote selection is determined for the received selection(s).

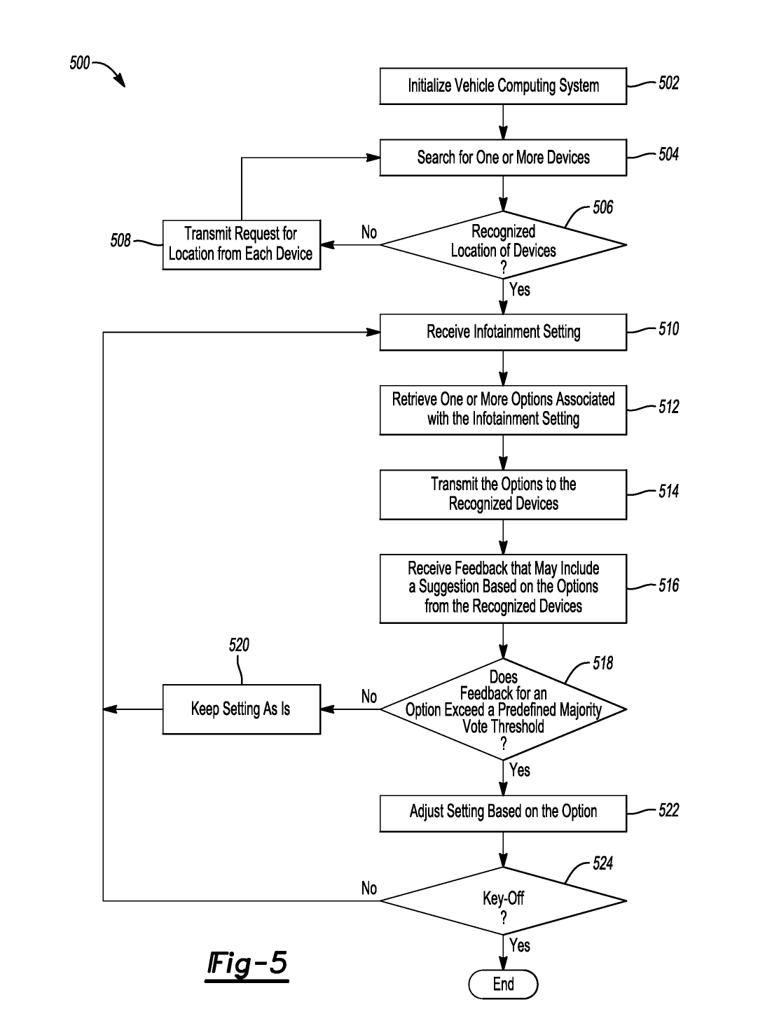

FIG. 5 is a flow chart illustrating an example method 500 of the VCS 1 communicating with the one or more remote devices 53. The method 500 may include instructions to control one or more vehicle settings based on received feedback from a vehicle occupant associated with at least one of the remote devices 53. The method 500 may be implemented using software code contained within the VCS 1. In other embodiments, the method 500 may be implemented in other vehicle controllers (one or more modules, for example), or distributed among multiple vehicle modules.

Referring again to FIG. 5, the vehicle and its components illustrated in FIG. 1 through FIG. 4 are referenced throughout the discussion of the method 500 to facilitate understanding of various aspects of the present disclosure. The method 500 of controlling a vehicle feature/function (vehicle settings, for example) based on feedback from one or more vehicle occupants via a communication link with the remote devices 53 may be implemented through a computer algorithm, machine executable code, or software instructions programmed into a suitable programmable logic device(s) of the vehicle, such as the processor 3, the device processor, another controller in communication with the vehicle computing system, or a combination thereof. Although the various operations shown in the flowchart diagram 500 appear to occur in a chronological sequence, at least some of the operations may occur in a different order, and some operations may be performed concurrently or not at all.

In operation 502, the VCS 1 may be initialized and enabled based on a key-on position or state of an ignition system. The VCS 1 may initialize one or more applications for execution. In response to the initialization of the VCS 1, the system may display one or more applications at a user interface. For example, the VCS 1 may execute an application configured to communicate with one or more remote devices 53 connected to the system via a communication link (USB, BLUETOOTH, etc., for example). The VCS 1 may manage the communication of data between the one or more remote devices 53 and the applications being executed on hardware at the system.

In operation 504, the VCS 1 may search for one or more devices 53 based on the initialization of the system. In response to a detected device within a vehicle cabin, the VCS 1 may determine if the device is recognized as a previously paired device while estimating a location for the device within the vehicle cabin in operation 506. If the location of the device is not recognized within the vehicle cabin, the VCS 1 may transmit a request for a seat location to each device in operation 508. For example, the VCS 1 may request that a vehicle occupant associated with the device enter the seat location (front seat passenger, backseat passenger, etc., for example) via the vehicle user interface screen. In another example, the vehicle occupant may enter the seat location via their remote device user interface screen and transmit the location to the VCS 1 via their device 53. If a driver device is identified as one of the one or more remote devices 53, the VCS 1 may enable a lock-out feature to prevent communication associated with the infotainment setting to the driver device.

In operation 510, the VCS 1 may receive an infotainment setting at the vehicle user interface screen. In response to receiving the infotainment setting, the VCS 1 may retrieve one or more setting options associated with the infotainment setting in operation 512. For example, if a song is selected to play via the vehicle infotainment system, the VCS 1 may retrieve several song playing settings including but not limited to, a skip song setting, a pause song setting, an increase volume request, a decrease volume request and/or a repeat song setting. In another example, the song playing settings may include a new song suggestion setting.

In operation 514, the VCS 1 may transmit the one or more options to the recognized device(s) communicating with the system. Continuing from the example above, the recognized device may receive the skip song setting, pause song setting, and/or repeat song setting so that the vehicle occupant may provide feedback via the remote device 53 associated with the occupant. In response to the vehicle occupant selecting the one or more options associated with the infotainment setting, the VCS 1 may receive feedback for the infotainment setting via the remote device 53 in operation 516. The received feedback from the remote device 53 may include a suggestion associated with the infotainment setting. For example, the suggestion may include a new song suggestion based on the song selected to play via the infotainment system. In another example, the suggestion may include a new destination based on a selected destination via a vehicle navigation system. The suggestion setting may be applied to other infotainment settings including, but not limited to climate control settings, interior lighting settings, movie settings and/or game settings.

In operation 518, in response to the received feedback from the one or more remote devices 53 communicating with the VCS 1, the system may determine if an option associated with the infotainment setting exceeds a predefined majority vote threshold. For example, the VCS 1 may determine if a particular option associated with the infotainment setting received more feedback from the vehicle occupants compared to the other options presented to the occupants. Continuing from the example above, if the VCS 1 received the skip song setting from two remote devices out of the three remote devices communicating with the system; the VCS 1 may execute the skip song setting.

The VCS 1 may have one or more arbitration rules that include giving an overruling designation to a predefined device and/or vehicle occupant if no majority is calculated. For example, if the VCS 1 receives a different selected option associated with the infotainment setting from each remote device, the system may execute the option selected by the front seat passenger since the system is unable to calculate a majority vote. If no option is selected from the one or more options associated with the infotainment setting and/or no majority vote is calculated for a selected option, the VCS 1 may keep the infotainment setting at the current setting in operation 520.

In operation 522, in response to feedback from the one or more remote devices 53 associated with vehicle occupants, the VCS 1 may adjust the infotainment setting based on the selected option. The VCS 1 may end the method of adjusting the infotainment setting via the one or more remote devices based on a detection of a key-off position of the ignition system in operation 524.

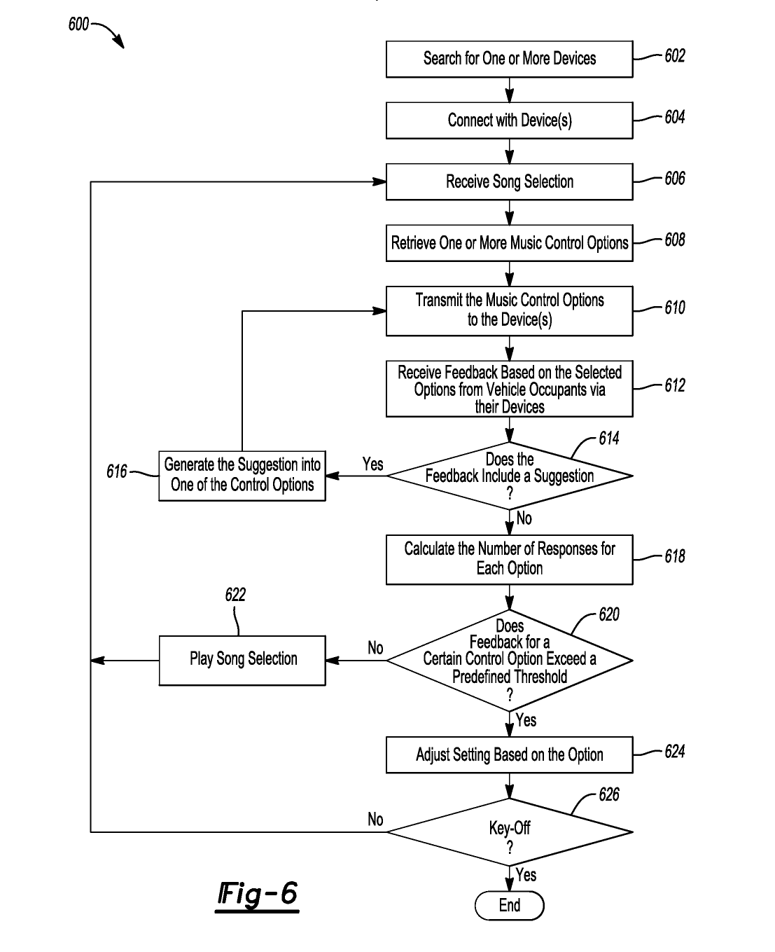

FIG. 6 is a flow chart illustrating an example method to adjust a music selection at the VCS 1 via the one or more remote devices 53. The method 600 may be implemented using software code contained within the VCS 1. In other embodiments, the method 600 may be implemented in other vehicle controllers, or distributed among multiple vehicle modules communicating with the one or more remote devices 53.

Referring again to FIG. 6, the vehicle and its components illustrated in FIG. 1 through FIG. 4 are referenced throughout the discussion of the method 600 to facilitate understanding of various aspects of the present disclosure. The method 600 of adjusting the music selection at the VCS 1 may be implemented through a computer algorithm, machine executable code, or software instructions programmed into a suitable programmable logic device(s) of the vehicle, such as the processor 3, the device processor, another controller in communication with the vehicle computing system, or a combination thereof. Although the various operations shown in the flowchart diagram 600 appear to occur in a chronological sequence, at least some of the operations may occur in a different order, and some operations may be performed concurrently or not at all.

In operation 602, in response to an initialized VCS 1, the system may search for one or more devices 53 within the vehicle cabin. The VCS 1 may connect with the devices based on a pairing process (a security handshake process, for example) in operation 604.

In operation 606, the VCS 1 may receive a song selection from a connected remote device 53. For example, the VCS 1 may be configured to receive a song from the remote device via an application being executed on hardware of the system. The VCS 1 may retrieve one or more music control options based on the song selection in operation 608. The one or more music control options include a vote to accept or deny playing the received song.

In operation 610, the VCS 1 may transmit the one or more music control options to the connected remote devices. Continuing from the example above, the VCS 1 may transmit the vote to accept or deny the received song selection so that the system may determine whether the other vehicle occupants want to listen to the song based on occupant feedback.

In operation 612, the VCS 1 may receive occupant feedback based on one or more selected options at the remote device(s). The VCS 1 may determine whether a suggestion for a new song was provided by the one or more remote devices in operation 614. For example, in response to receiving the one or more options related to the selected song, a vehicle occupant may transmit a new suggested song to the VCS 1. The VCS 1 may generate the new song suggestion into one of the control options to allow the vehicle occupants to provide feedback for the new suggestion in operation 616. In one example, the vehicle occupant providing the new song suggestion may not provide feedback associated with their suggestions. The system may prevent a vehicle occupant from providing a vote (feedback, for example) favoring their suggestion associated with the selected option so that the system may calculate a majority based on feedback from the other vehicle occupants.

In operation 618, the VCS 1 may calculate the number of responses received for each option to determine whether a majority of the vehicle occupants want to implement a specific option. The VCS 1 may determine that the feedback for a certain control option exceeds a predefined threshold value in operation 620. For example, the predefined threshold value is a calculated ratio based on a majority vote that takes into consideration a number of options selected and a number of remote devices connected to the system. In response to the one or more music control options not exceeding the predefined threshold, the VCS may play the received selected song in operation 622.

In operation 624, the VCS 1 may adjust the selected song based on a selected music control option exceeding the predefined threshold. For example, the VCS 1 may skip the selected song if the skip request is received by a majority of the connected devices communicating with the system. In another example, the VCS 1 may play the new song suggestion if the associated option for the new song exceeds the predefined threshold value. The VCS 1 may end the method of controlling the infotainment setting via the one or more remote devices based on a detection of a key-off position of the ignition system in operation 626.

While representative embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and can be desirable for particular applications.

What is claimed is:

1. A vehicle system comprising:
a processor programed to,
receive a suggested infotainment setting via occupant input;
transmit the suggested infotainment setting to one or more devices for occupant feedback; and
control an infotainment feature in response to received occupant feedback to accept, reject, or modify the suggested infotainment setting.

2. The vehicle system of claim 1, wherein the processor is further programed to arbitrate the received occupant feedback by comparing a number of the accept, reject, or modify occupant feedback to a predefined threshold value.

3. The vehicle system of claim 2, wherein the processor is further programed to control the infotainment feature based on the suggested infotainment setting if the occupant feedback to accept exceeds the predefined threshold value.

4. The vehicle system of claim 3, wherein the processor is further programed to receive the occupant feedback to modify and output the occupant feedback to modify the suggested infotainment setting to the one or more devices for additional occupant feedback.

5. The vehicle system of claim 2, wherein the infotainment feature is a navigation system and the processor is further programed to modify the navigation system based on the received occupant feedback to modify being a suggested destination.

6. The vehicle system of claim 5, wherein the navigation system outputs a route from a current vehicle location to the suggested destination via a vehicle interface display.

7. The vehicle system of claim 1, wherein the processor is further programed to detect a device location within a vehicle cabin for the one or more devices communicating with the processor.

8. The vehicle system of claim 7, wherein the processor is further programed to, in response to the device location identifying a driver device as the one or more devices, enable a lock-out feature to prevent the received occupant feedback associated with the infotainment setting being communicated to the driver device.

9. The vehicle system of claim 7, wherein the processor is further programed to, in response to the device location identifying a front seat passenger device as the one or more devices, enable an over-ride feature to allow the front seat passenger device to control the infotainment feature if the received occupant feedback to accept, reject, or modify the suggested infotainment setting does not exceed a predefined threshold value.

10. A method comprising:
transmitting, via a vehicle processor, a setting suggestion request to one or more occupant devices;
receiving a response to the setting suggestion request from the one or more occupant devices; and
outputting an option list having the response from each of the occupant devices to a designated occupant device to allow the designated device to control an infotainment feature based on an occupant selected response from the option list.

11. The method of claim 10, further comprising, in response to the occupant selected response, controlling the infotainment feature.

12. The method of claim 11, wherein the response to the setting suggestion is a music selection and the infotainment feature is an infotainment system configured to execute the music selection.

13. The method of claim 12, wherein the music selection is at least one of a song request, a skip request for a current song playing, an increase volume request for the infotainment system, and a decrease volume request for the infotainment system.

14. The method of claim 13, further comprising, outputting the option list having the at least one of the song request, the skip request for the current song playing, the increase volume request and the decrease volume request at the designated device.

15. The method of claim 14, wherein the designated device enables a user to select from the option list based on the received music selection from the one or more devices.

16. The method of claim 14, further comprising adjusting the vehicle infotainment system based on user selection from the outputted option list via the designed device.

17. A computer program product embodied in a non-transitory computer readable medium having stored instructions for programming a processor, comprising instructions for:
transmitting a setting adjustment option to one or more devices via a transceiver for occupant feedback to accept, reject, or modify an infotainment feature; and
controlling the infotainment feature in response to received occupant feedback.

18. The computer program product of claim 17, wherein controlling the infotainment feature includes comparing the occupant feedback to a predefined majority threshold value based on multiplying a predefined majority factor to a total amount of occupant feedback received from each device for the at least one of the accept, reject and modify feedback.

19. The computer program product of claim 17, wherein the setting adjustment option is at least one of a destination input for a navigation system, a music selection for a vehicle infotainment system, and a climate setting for a climate control system.

20. The computer program product of claim 17, wherein the non-transitory computer readable medium further comprises instructions for, in response to the occupant feedback to modify the setting adjustment option, outputting the modified setting adjustment option to the one or more devices; and controlling the infotainment feature based on the modified setting adjustment option.
